(19) United States
(12) Patent Application Publication
(10) Pub. No.: US 2011/0134679 A1
(43) Pub. Date: Jun. 9, 2011

(54) MEMORY MODULE HAVING OPTICAL BEAM PATH, APPARATUS INCLUDING THE MODULE, AND METHOD OF FABRICATING THE MODULE

(76) Inventors: Sung-dong SUH, Seoul (KR); Kyoung-won Na, Seoul (KR); Kyoung-ho Ha, Seoul (KR); Seong-gu Kim, Pyeongtaek-si (KR); Ho-chul Ji, Yongin-si (KR); In-sung Joe, Seoul (KR)

(21) Appl. No.: 12/961,542

(22) Filed: Dec. 7, 2010

(30) Foreign Application Priority Data
Dec. 8, 2009 (KR) 10-2009-0121396

(51) Int. Cl. G11C 13/04; G02B 6/32; H05K 3/30

(52) U.S. Cl. 365/64; 385/33; 29/832

(57) ABSTRACT

A memory module may include at least one memory package including an optical signal input/output (I/O) unit and a first optical beam path and a printed circuit board (PCB) on which the memory package is mounted. The PCB may have a second optical beam path configured to transmit an optical signal to the optical signal I/O unit. The memory module may further include a connecting body configured to mount the memory package on the PCB and match a refractive index of the first optical beam path with a refractive index of the second optical beam path.

### CROSS-REFERENCE TO RELATED APPLICATIONS

This application claims priority under 35 U.S.C. §119 to Korean Patent Application No. 10-2009-0121396, filed on Dec. 8, 2009, in the Korean Intellectual Property Office (KIPO), the disclosure of which is incorporated herein in its entirety by reference.

### BACKGROUND

1. Field

Example embodiments of the invention relate to a memory module and a method of fabricating the same, and more particularly, to a memory module using an optical signal and a method of fabricating the same.

2. Description of the Related Art

A computer may include a plurality of memory units, such as a dynamic random access memory (DRAM) unit or a synchronous dynamic RAM (SDRAM). The DRAM and the SDRAM allow for data to be searched and stored. Some conventional computers have discrete memory units directly mounted on a computer main board, that is, a system board or a mother board. Due to increases in the capacity and complexity of computers and programs executed using computers, memory units with higher capacity and speed have been required. However, a conventional system board cannot accommodate a sufficient number of discrete memory units.

In order to overcome these drawbacks, a memory module including a plurality of memory units, for example, a single in-line memory module (SIMM) or a dual in-line memory module (DIMM), has been proposed and used so far. This memory module may exchange electric signals with a controller, such as a central processing unit (CPU), and process data stored in a memory chip, for example, store the data and/or search for the data.

### SUMMARY

Example embodiments of the invention provide a memory module including a high-speed interconnection disposed between a memory and a memory controller to process data at high speed. Particularly, example embodiments provide a memory module including an optical beam path capable of replacing an electric signal, which is conventionally transmitted through an electrical link, with an optical signal transmitted via an optical link, an electrical and electronic apparatus including the memory module, and a method of fabricating the memory module.

In accordance with example embodiments, a memory module may include at least one memory package including an optical signal input/output (I/O) unit and a first optical beam path, a printed circuit board (PCB) on which the memory package is mounted, the PCB having a second optical beam path configured to transmit an optical signal to the optical signal I/O unit, and a connecting body configured to mount the memory package on the PCB and match a refractive index of the first optical beam path with a refractive index of the second optical beam path.

In accordance with example embodiments, a method of manufacturing a memory module may include manufacturing a memory package including an optical signal I/O unit, forming an optical beam path in a PCB to enable transmission of an optical signal to the optical signal I/O unit, and mounting the memory package on the PCB using a medium material.

According to an aspect of the example embodiments, there is provided a memory module including: at least one memory package including an optical signal input/output (I/O) unit; a printed circuit board (PCB) on which the memory package is mounted, the PCB having an optical beam path through which an optical signal is transmitted to the optical signal I/O unit; and a medium unit configured to mount the memory package on the PCB and match the refractive index of the optical signal I/O unit with that refractive index of the optical beam path.

The optical beam path of the PCB may include: an optical waveguide installed in a horizontal direction of the PCB and having a core and a clad; a reflector installed at an end portion of the optical waveguide and configured to vertically reflect beams; and a drum lens installed in a vertical direction of the PCB and configured to collimate or focus the beams reflected by the reflector in a direction toward the optical signal I/O unit. For example, the core of the optical waveguide may be formed of silicon, and the clad of the optical waveguide may be formed of silicon oxide (SiO₂). The drum lens may be formed of silicon oxide and include a convex lens formed in a top end disposed toward the optical I/O unit.

The optical I/O unit may include a grating coupler or Gaussian grating coupler configured to selectively input or output the optical signal according to a wavelength. Also, the memory package may include a support substrate configured to support a memory chip. An optical beam path may be formed in a portion of the support substrate corresponding to the optical I/O unit. The optical beam path of the support substrate may be of a drum lens type including a convex lens formed in a top end disposed toward the PCB. The medium unit may include: solder balls configured to mount the memory package on the PCB; and a refractive index matching unit formed of a transparent material, which allows transmission of the optical signal. The refractive index matching unit may be interposed between the optical beam path of the memory package and the optical beam path of the PCB and configured to match a refractive index of the optical beam path of the memory package with a refractive index of the optical beam path of the PCB.

According to another aspect of the example embodiments, an electrical and electronic apparatus includes: the memory module; a light source configured to generate an optical signal to be transmitted to the memory module; a central processing unit (CPU) or microprocessor (MP) including an operator and controller configured to process and control data; an optic/electric converter configured to convert the optical signal transmitted from the memory module into an electric signal, transmit the electric signal to the CPU or MP, convert the electric signal transmitted from the CPU or MP into an optical signal, and transmit the optical signal to the memory module; and a system board on which the memory module, the light source, one of the CPU and the MP, and the optic/electric converter are mounted.

An optical waveguide configured to transmit the optical signal may be formed on the system board between the memory module and the optic/electric converter.

According to another aspect of the example embodiments, a method of manufacturing a memory module includes: manufacturing a memory package including an optical I/O unit; forming an optical beam path in a PCB to enable transmission of an optical signal to the optical I/O unit; and mounting the memory package on the PCB using a medium material.

The formation of the drum lens may include: forming a predetermined groove on a portion of the optical waveguide corresponding to the reflector; depositing silicon oxide to fill the groove with the silicon oxide; and convexly forming a top surface of the silicon oxide using an annealing or reflow process.

### BRIEF DESCRIPTION OF THE DRAWINGS

Example embodiments of the invention will be more clearly understood from the following detailed description taken in conjunction with the accompanying drawings in which:

FIG. 1 is a cross-sectional view of a memory module according to an example embodiment;

FIG. 2 is a cross-sectional view of the memory module of FIG. 1, according to a modified example embodiment;

FIG. 3 is a cross-sectional view of the memory module of FIG. 1, according to another modified example embodiment;

FIG. 4A is a detailed cross-sectional view of a printed circuit board (PCB) of FIG. 1;

FIG. 4B is a detailed cross-sectional view of a printed circuit board (PCB) of FIG. 2 or 3;

FIG. 5 is a construction diagram for explaining a principle that light is collimated or focused through a drum lens formed on the PCB of FIG. 4B;

FIGS. 6A and 6B are diagrams for explaining calculation of a coupling ratio due to mismatch of a mode field;

FIG. 7 is a cross-sectional view of a grating coupler or Gaussian grating coupler applied to an optical input/output (I/O) unit according to an example embodiment;

FIG. 8 is a diagram for explaining an optical coupling principle using a grating coupler or a Gaussian grating coupler;

FIG. 9 is a perspective view of an apparatus including a memory module according to another example embodiment;

FIGS. 10A through 10C are cross-sectional views illustrating a process of forming a drum lens on a PCB in a method of manufacturing a memory module according to another example embodiment;

FIGS. 11A and 11B are a plan view and side view, respectively, of a PCB having a drum lens; and

FIG. 12 is a cross-sectional view of a memory module according to an example embodiment.

### DETAILED DESCRIPTION OF THE EXAMPLE EMBODIMENTS

Example embodiments will now be described more fully with reference to the accompanying drawings in which example embodiments are shown. Example embodiments may, however, be embodied in different forms and should not be construed as limited to example embodiments set forth herein. Rather, example embodiments are provided so that this disclosure is thorough and complete and fully conveys the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present inventive concept. As used herein, the singular forms “a,” “an” and “the” are intended to include the plural faiths as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention will now be described more fully with reference to the accompanying drawings, in which example embodiments of the invention are shown. It will also be understood that when a layer is referred to as being “on” another layer or substrate, it can be directly on the other layer or substrate, or intervening layers that may also be present. In the drawings, the thicknesses of layers and regions are exaggerated for clarity. Like reference numerals in the drawings denote like elements, and thus their description will be omitted. Meanwhile, the terminology used herein is for the purpose of describing particular embodiments only and is not intended to be limiting of the inventive concept.

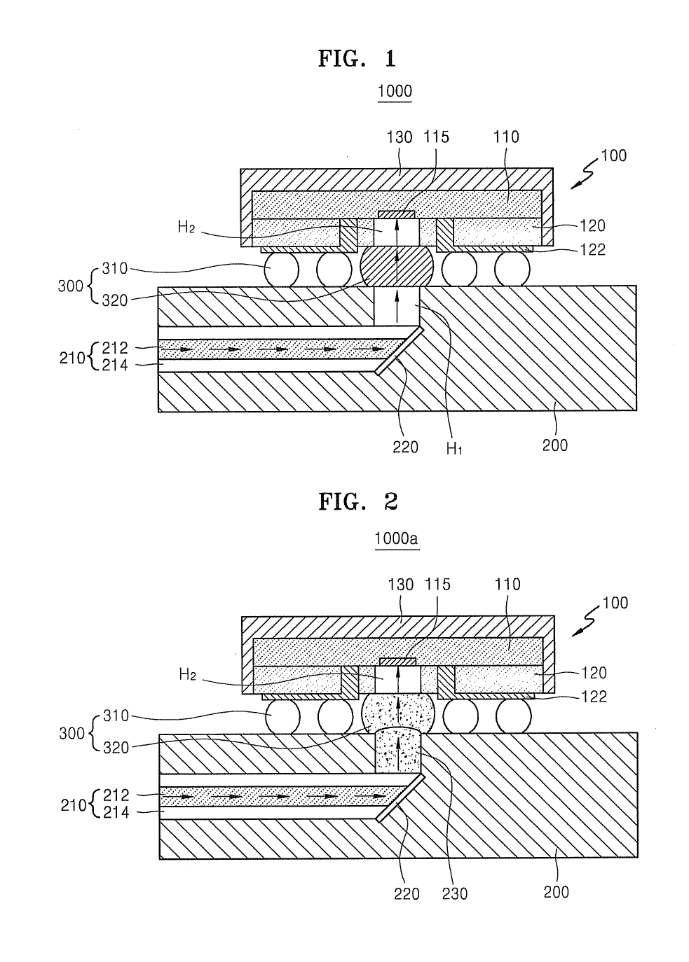

FIG. 1 is a cross-sectional view of a memory module according to an example embodiment.

Referring to FIG. 1, a memory module 1000 according to an example embodiment may include a memory package 100, a printed circuit board (PCB) 200, and a medium unit 300. The medium unit 300 is an example of a connecting body that may be used to connect the memory package 100 to the PCB 200.

The memory package 100 may include a memory chip 110, a support substrate 120, and an encapsulant 130. The memory chip 110 may be a dynamic memory chip, such as a dynamic random access memory (DRAM), a synchronous dynamic RAM (SDRAM), a double date rate-SDRAM (DDR-SDRAM), a double date rate2-SDRAM (DDR2-SDRAM), a double date rate3-SDRAM (DDR3-SDRAM), and a Rambus-DRAM (RDRAM). Alternatively, the memory chip 110 may be a flash memory chip, such as a NAND flash memory or a NOR flash memory.

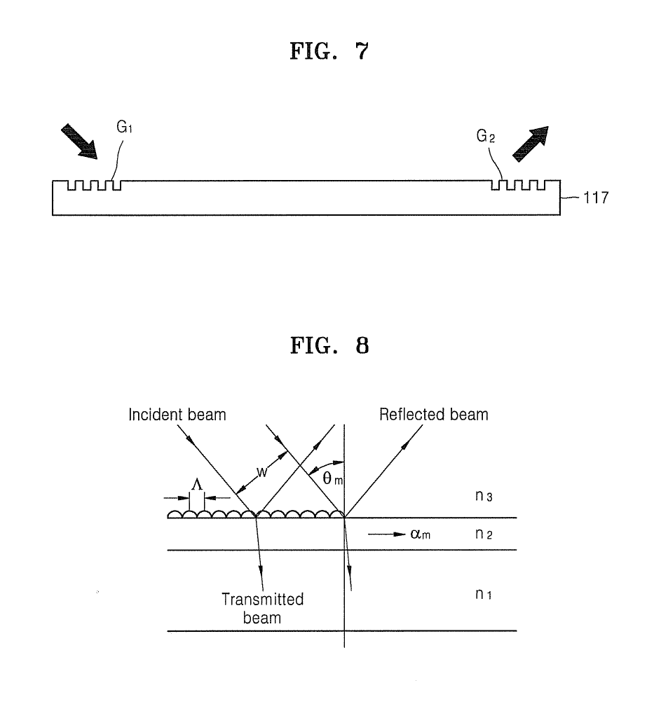

Unlike a conventional memory chip, the memory chip 110 may include an optical input/output (I/O) unit 115 capable of receiving and outputting an optical signal. The optical I/O unit 115 may convert external optical signals into electric signals and transmit the electric signals to cells of the memory chip 110. Also, the optical I/O unit 115 may receive electric signals from the cells of the memory chip 110, convert the electric signals into optical signals, and externally transmit the optical signals. Meanwhile, the optical I/O unit 115 may include a grating coupler or a Gaussian grating coupler in order to increase a coupling rate of input and output optical signals. A further detailed description of the grating coupler or Gaussian grating coupler will be presented later with reference to FIGS. 7 and 8.

The support substrate 120 may be combined with the memory chip 110 to support the memory chip 110, and an interconnection 122 may be formed inside and outside the support substrate 120 and electrically connected to the memory chip 110. A power supply voltage or a ground voltage may be applied to the memory chip 110 through the interconnection 122. In this example embodiment, an optical beam path for transmission of optical signals may be formed in the center of the support substrate 120 corresponding to the optical I/O unit 115 of the memory chip 110. According to the present example embodiment, the optical beam path formed on the support substrate 120 may be a groove H₂.

The encapsulant 130, which may encapsulate the memory chip 110, may be a polymer mold formed of a resin.

According to the present example embodiment, the optical beam path through which optical signals may be transmitted may be formed in the PCB 200 unlike in the conventional case. The optical beam path may include an optical waveguide 210, a reflector 220, and a groove H₁. The optical waveguide 210 may include a core 212 for guiding or confining light, and transmitting light and a clad 214 configured to surround the core 212. As a difference in refractive index between the core 212 and the clad 214 of the optical waveguide 210 increases, light may be optically confined more tightly. Thus, the optical guiding efficiency of the optical waveguide 210 may be increased, thereby enabling formation of a smaller optical beam path.

According to the present example embodiment, the core 212 may be formed of silicon, while the clad 214 may be formed of silicon oxide (SiO₂). A difference in refractive index between silicon and silicon oxide (SiO₂) may be about 2.0. When the optical waveguide 210 is formed using the above-described materials, the core 212 may be formed to have a very small section with a width of about 500 nm or less and a height of about 250 nm or less in order to maintain a single-mode condition of light transmitted therethrough. This offers considerable advantages over a conventional art alternative that uses a single-mode fiber (SMF). In the conventional art, when a single-mode fiber (SMF) mode, which has been widely used for conventional optical communications, is used to couple light with the optical waveguide 210 with the very small size, a coupling efficiency may be greatly degraded because an SMF has a mode field diameter of about 10 μm or more.

Thus, light may be input to or output from the optical waveguide 210 using the grating coupler. Also, light incident onto the grating coupler may be collimated light having a high quality in order to further increase the coupling efficiency. However, since light incident from a light source, such as a laser diode (LD), onto the optical waveguide 210 of the PCB 200 is already collimated light having a high quality, the optical coupling efficiency between the light source and the optical waveguide 210 may not be considered.

In this example embodiment, a photodiode (PD) may be incorporated into the optical I/O unit 115 to serve as a light receiving unit. When light is incident from the optical waveguide 210 to the optical I/O unit 115, since the photodiode (PD) serving as a light receiving unit is installed, optical coupling efficiency may be determined by the size of an active region of the PD and the size of incident light rather than the quality of light incident to the PD. Thus, the size of light incident to the PD (or light output from the optical waveguide 210) may be approximately controlled. For example, light output from the optical waveguide 210 may be collimated light. A further detailed description of the coupling efficiency will be described later with reference to FIGS. 6A and 6B.

The reflector 220 (e.g., mirror) for reflecting light at an angle of 90° may be formed at an end portion of the optical waveguide light 210. The reflector 220 may be inclined at an angle of 45° with respect to the optical waveguide 210 and reflect light transmitted through the optical waveguide 210 at an angle of 90° with respect to the optical waveguide 210.

Light reflected by the reflector 220 may be propagated through the groove H₁ formed in a vertical direction in the PCB 200 and input to the optical I/O unit 115 through the a refractive index matching unit 320 (an example of a matching body) and groove H₂ formed in the support substrate 120.

The medium unit 300 may include solder balls 310 and the refractive index matching unit 320. The refractive index matching unit 320 may be formed of a transparent material between the optical beam path of the support substrate 120 and the optical beam path of the PCB 200 to appropriately match the refractive index of the optical beam path of the PCB with the refractive index of the optical beam path of the support substrate 120. Thus, the refractive index matching unit 320 may be formed of a material having such a refractive index as to appropriately match the refractive index of the optical beam path of the PCB with the refractive index of the optical beam path of the support substrate 120. In the present example embodiment, since the optical beam paths of the support substrate 120 and the PCB 200 that contact the refractive index matching unit 320 are grooves H₁ and H₂, the refractive index of the refractive index matching unit 320 may not be considered.

The solder balls 310 may correspond to portions of the medium unit 300 other than the refractive index matching unit 320 and may function to stably mount the memory package 100 on the PCB 200. In this example embodiment, the solder balls 310 may electrically connect the interconnection 122 of the support substrate 120 with an interconnection (not shown) of the PCB 200 to enable application of a power supply voltage or a ground voltage to the memory chip 110. However, example embodiments are not limited thereto, for example, in other example embodiments the solder balls do not electrically connect the support substrate 120 to the PCB 200. In another example embodiment, solder balls 310 and the refracting index matching unit 320 may not be present and the interconnection 122 of the support substrate 120 may be directly attached to the PCB 200 or to pads (not shown) on a surface of the PCB 200 to electrically connect the support substrate 120 to the PCB 200. In other example embodiments, studs may be used in lieu of solder balls.

In the memory module 1000 according to the present example embodiment, the optical I/O unit 115 may be installed in the memory chip 110, and the optical beam paths for transmitting optical signals may be formed in the support substrate 120 and the PCB 200. Thus, the memory chip 110 may be controlled using optical signals instead of conventional electric signals so that data can be processed at high speed.

FIG. 2 is a cross-sectional view of the memory module of FIG. 1, according to a modified example embodiment.

Referring to FIG. 2, a memory module 1000a according to the modified example embodiment may be similar to the memory module 1000 of FIG. 1 except for the groove H₁ corresponding to the optical beam path formed on the PCB 200. Thus, a description of the same components as described with reference to FIG. 1 will be omitted.

In the memory module 1000a of the modified example embodiment, the optical beam path formed on the PCB 200 may include an optical waveguide 210, a reflector 220, and a drum lens 230. That is, the groove H₁ of the PCB 200 of FIG. 1 may be replaced by the drum lens 230. As described above, light output from the optical waveguide 210 may be collimated to be incident onto an optical I/O unit 115 with high optical coupling efficiency. In general, light transmitted in a medium may diverge in air. It is obvious that when light diverges, optical coupling efficiency is reduced. Thus, light output from the optical waveguide 210 should not diverge but be collimated or focused on the center to some extent. When the light output from the optical waveguide 210 is focused, the light may not be focused on one point like in the case of a typical convex lens but be slightly focused like in the case of a collimated light.

The drum lens 230 may be formed instead of the groove H₁ of the PCB 200 of FIG. 1 to enable the light output from the optical waveguide 210 to be collimated or slightly focused. The drum lens 230 may be a convex lens having an upper end with a radius of curvature sufficient to obtain a collimated or slightly focused effect. The formation of the drum lens 230 may include depositing silicon oxide in a portion corresponding to the groove H₁ of FIG. 1 and swelling the silicon oxide using a reflow process.

By forming the drum lens 230 in the groove portion of the PCB 200, a refractive index matching unit 320 formed on the drum lens 230 may have a slightly different shape from the refractive index matching unit 320 of FIG. 1. Specifically, the refractive index matching unit 320 may be not flattened but curved inward due to an upper convex lens of the drum lens 320.

In the memory module 1000a of the present example embodiment, the drum lens 230 is formed in the groove portion of the PCB 200 so that light output from the optical waveguide 210 may be collimated or slightly focused. As a result, optical signals may be transmitted to the optical I/O unit 115 with high optical coupling efficiency.

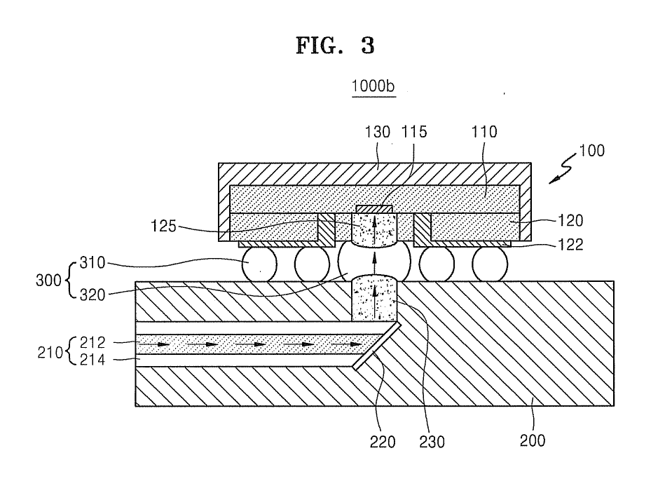

FIG. 3 is a cross-sectional view of the memory module of FIG. 1, according to another modified example embodiment.

Referring to FIG. 3, a memory module 1000b of the present example embodiment may be similar to the memory module 1000 of FIG. 2 except for the groove H₂ corresponding to the optical beam path formed on the support substrate 120. Thus, a description of the same components as described with reference to FIG. 1 or 2 will be omitted.

In the memory module 1000b of the present example embodiment, a drum lens 125, which may be similar to the drum lens 230 of the underlying PCB 200 of FIG. 2, may be fanned in the groove H₂ corresponding to the optical beam path of the support substrate 120. The drum lens 125 may include a convex lens having a radius of curvature sufficient to obtain a collimated or slightly focused effect. Like the drum lens 230 formed on the PCB 200, the formation of the drum lens 125 may include depositing silicon oxide in a portion corresponding to the groove H₂ of FIG. 1 and swelling the silicon oxide using a reflow process.

As described above, the optical beam path of the support substrate 120 may be formed to correspond to the type of the drum lens 125 so that an optical signal output from the optical I/O unit 115 may be collimated or slightly focused and incident to the optical beam path of the underlying PCB 200, thereby increasing the optical coupling efficiency. However, when the optical I/O unit 115 includes a grating coupler or a Gaussian grating coupler, since light output from the grating coupler or Gaussian grating coupler is collimated to some extent, the optical beam path of the support substrate 120 may not be necessarily formed as a drum lens type.

In case that the drum lens 125 is formed in the groove H₂ of the support substrate 120, the refractive index matching unit 320 formed under the drum lens 125 may have a slightly different shape from the refractive index matching unit 320 of FIG. 1 or FIG. 2. That is, the refractive index matching unit 320 of FIG. 3 may be not flattened but curved inward due to a lower convex lens of the drum lens 125.

In the memory module 1000b of the present example embodiment, the drum lens 230 may be formed in the groove portion of the PCB 200 and the drum lens 125 may be formed in the groove portion of the support substrate 120 so that light output from the optical waveguide 210 or the optical I/O unit 115 may be collimated or slightly focused to the optical I/O unit 115 or the optical waveguide 210. As a result, optical signals may be input to or output from the optical I/O unit 115 or the optical waveguide 210 with high optical coupling efficiency.

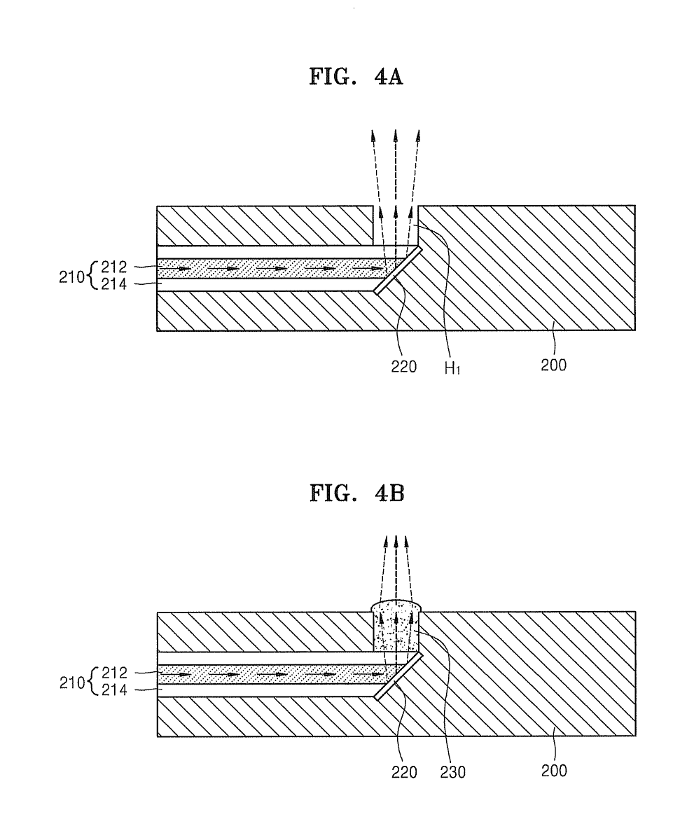

FIG. 4A is a detailed cross-sectional view of the PCB of FIG. 1.

Referring to FIG. 4A, when light is transmitted through the groove H₁ formed on the PCB 200 like in the memory module 100 of FIG. 1, light may diverge and be optically coupled with the optical I/O unit 115 with degraded optical coupling efficiency. Of course, when the groove H₁ has a very small depth, a difference in optical coupling efficiency may be very small.

FIG. 4B is a detailed cross-sectional view of the PCB of FIG. 2 or 3.

Referring to FIG. 4B, when the drum lens 230 is formed in the portion of the PCB 200 corresponding to the groove H₁ like in the memory module 1000a of FIG. 2 or the memory module 1000b of FIG. 3, light output from the optical waveguide 210 through the reflector 220 may be collimated or lightly focused by the drum lens 230 so that the light may be optically coupled with the optical I/O unit 115 with improved optical coupling efficiency.

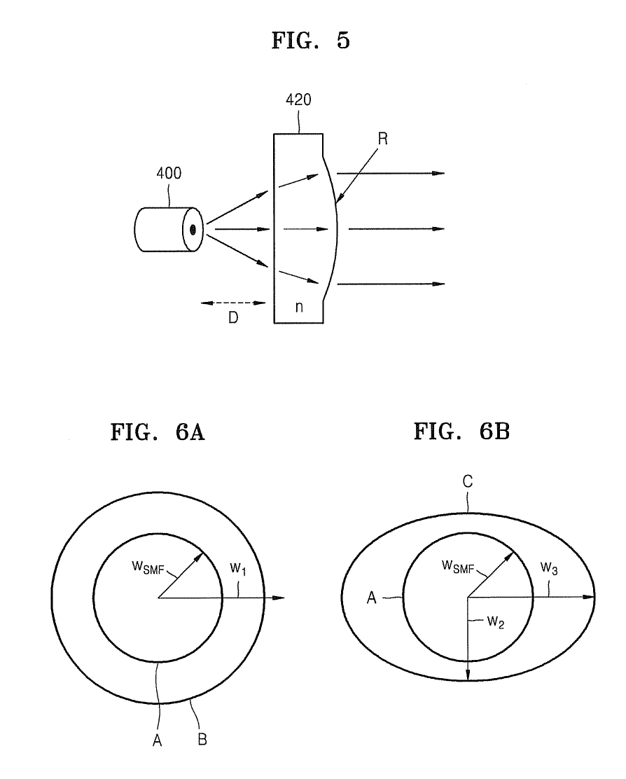

FIG. 5 is a construction diagram for explaining a principle that light is collimated or focused through a drum lens formed on the PCB of FIG. 4B.

Referring to FIG. 5, a path of light passing through a lens 420 may typically depend on a distance (i.e., working distance D) between a light source 400 and the lens 420, a refractive index n of the lens 420, and a radius of curvature R of the lens 420. This principle may be quantitatively explained in consideration of ray optics and Gaussian optics. Thus, a drum lens according to the example embodiments may be formed in the groove H₁ of the PCB 200 or the groove H₂ of the support substrate 120 based on the above-described principle.

FIGS. 6A and 6B are diagrams for explaining calculation of a coupling ratio due to mismatch of a mode field.

As described above, since a PD is installed in an optical I/O unit 115, optical coupling efficiency may be determined simply by the size of the active region of the PD and the size of incident light rather than the quality of light incident to the PD. Thus, when a mismatch of the size of light (i.e., a mismatch of a mode field profile) occurs between respective light beams, optical coupling efficiency may be explained as follows.

First, when circular light is transmitted through an SMF as shown in FIG. 6A, optical coupling efficiency η1 may be expressed as in Equation 1:

η1=(2w₁w_{SMF})/(w₁²+w_{SMF}²) (1),

wherein w_{SMF} denotes the radius of a section A of light that may be transmitted through the SMF, and w₁ denotes the radius of a section B of light incident to the SMF. As can be seen from Equation 1, the optical coupling efficiency is always less than 1 except a case where the value w_{SMF} is equal to the value w₁.

Next, when elliptical light is transmitted through an SMF as shown in FIG. 6B, optical coupling efficiency η2 may be expressed as in Equation 2:

η2=(4w₃w₂w_{SMF}²)/{(w₃²+w_{SMF}²)(w₂²+w_{SMF}²)} (2),

wherein w_{SMF} denotes the radius of a section A of light that may be transmitted through the SMF, w₃ denotes the major-axial radius of a section C of elliptical light incident to the SMF, and w₂ denotes the minor-axial radius of the section C of the elliptical light. The optical coupling efficiency η2 of elliptical light cannot be 1 according to Equation 2. However, it can be seen that it is possible to make the value w_{SMF} be approximately equal to the value w₂, to increase the optical coupling efficiency η2.

FIG. 7 is a cross-sectional view of a grating coupler or Gaussian grating coupler applied to an optical I/O unit according to example embodiments.

Referring to FIG. 7, a grating coupler 117 may be embodied by forming gratings G₁ and G₂ at both ends of an optical waveguide. A grating coupler formed more precisely based on Gaussian optics may be referred to as a Gaussian grating coupler.

A grating size (i.e., grating period) of the grating coupler 117 may depend on the width W and wave vector k-vector of incident light. By forming appropriate gratings in the grating coupler 117, the corresponding incident light may be optically coupled with the grating coupler 117 with high optical coupling efficiency. A condition for coupling light with the grating coupler 117 will be described with reference to FIG. 8.

FIG. 8 is a diagram for explaining an optical coupling principle using a grating coupler or a Gaussian grating coupler.

Referring to FIG. 8, the phase of incident light should match that of a grating coupler so that the incident light may be optically coupled with the grating coupler with high optical coupling efficiency. Thus, a phase matching condition may be expressed as in Equation 3:

β_{ν}=β₀+ν2π/Λ (3),

wherein ν is an integer, Λ denotes a grating period, β_{ν} denotes the phase of light in a ν-th mode, and β₀ denotes the phase of light in a fundamental mode.

Also, a guiding condition for confining light in an optical waveguide may be expressed as in Equation 4:

αₘ=κn₃ sin θₘ=(2π/λ₀n₃)sin θₘ (4),

wherein m is an integer, λ₀ denotes the wavelength of light in the fundamental mode, and κ denotes a wavenumber, that is, the reciprocal of a wavelength. Also, αₘ denotes a condition value of refractive index of light of an m-th mode, and θₘ denotes an incidence angle of the light of the m-th mode. Meanwhile, in FIG. 8, w denotes the width of incident light, n₁ denotes the refractive index of a clad, n₂ denotes the refractive index of a clad, and n₃ denotes the refractive index of the outside of the optical waveguide or the refractive index of the clad.

In order to guide the incident light in the optical waveguide, the inequality condition κn₃<αₘ<κn₂ should be satisfied.

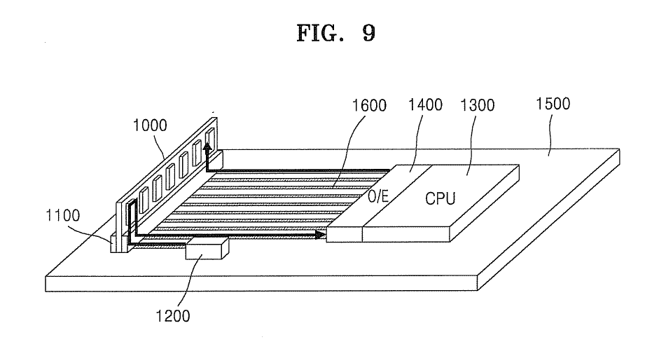

FIG. 9 is a perspective view of an apparatus including a memory module according to another example embodiment.

Referring to FIG. 9, the apparatus of the present example embodiment may include a memory module 1000, a light source 1200, a CPU 1300, an optic/electric converter 1400, and a system board 1500.

The memory module 1000 may be the memory module described with reference to FIG. 1. Thus, an optical I/O unit 115 may be formed in a memory chip 110, and an optical beam path may be formed on a PCB 200. Alternatively, the memory module 1000 included in the apparatus of the present example embodiment may be the memory module 1000a of FIG. 2 or the memory module 1000b of FIG. 3. The memory module 1000 may combine with the system board 1500 through a socket 1100 formed in the system board 1500.

The light source 1200 may be an optical device, such as a laser diode (LD), which may generate collimated light and supply the collimated light to the memory module 1000. The CPU 1300 may include an operator and a controller to process data or generally control respective components of a system. Although only the CPU 1300 is mentioned, the CPU 1300 may be replaced with a microprocessor (MP) used for a compact computer or a mobile device.

The optic/electric converter 1400 may convert an optical signal transmitted from the memory module 1000 into an electric signal, transmit the electric signal to the CPU 1300, convert an electric signal transmitted from the CPU 1300 into an optical signal, and transmit the optical signal to the memory module 1000. The optic/electric converter 1400 may generate an optical signal and directly transmit the optical signal to the memory module 1000. However, generally, the light source 1200 typically generates light, the light is converted into an optical signal by loading data signals, and the optical signal is transmitted to the memory module 1000.

The foregoing components, that is, the memory module 1000, the light source 1200, the CPU 1300, and the optic/electric converter 1400 may be mounted on the system board 1500. Meanwhile, an optical waveguide 1600 configured to transmit the optical signal may be formed between the memory module 1000 and the optic/electric converter 1400.

In the electrical and electronic apparatus of the present example embodiment, the optical I/O unit 115 and the optical beam path, which are configured to transmit the optical signal, may be fanned in the memory module 1000. Also, the optic/electric converter 1400 may be installed at the front end of the CPU 1300 to convert the optical signal into an electric signal and convert the electric signal into the optical signal. As a result, the electrical and electronic apparatus may process and control data using the optical signal at high speed.

A process of manufacturing the memory module of FIGS. 1 through 3 will now be described with reference to FIGS. 1 through 3.

A memory package 100 including an optical I/O unit 115 may be manufactured. More specifically, the optical I/O unit 115 may be formed in the memory chip 110. The optical I/O unit 115 may be electrically connected to cells of the memory chip 110. Thus, the optical I/O unit 115 may convert received optical signals into electric signals, transmit the electric signals to the respective cells, convert the electric signals received from the respective cells into optical signals, and transmit the optical signals to an optical waveguide 210 of a PCB 200. Meanwhile, an interconnection 122 may be formed inside and outside a support substrate 120, and an optical beam path may be formed in a portion corresponding the optical I/O unit 115. The optical beam path may be a groove H₁ or a drum lens 125 formed of silicon oxide.

After the optical I/O unit 115 is formed in the memory chip 110 and the optical beam path is formed toward the support substrate 120, the memory chip 110 may be combined with the support substrate 120. The combination of the memory chip 110 with the support substrate 120 may be performed using a conductive adhesive. Thereafter, the memory chip 110 may be encapsulated using an encapsulant 130. Meanwhile, solder balls 310 may be formed under the support substrate 120 before the encapsulation process if required.

After forming the memory package 100, an interconnection may be fanned in the PCB 200, and an optical beam path may be formed in the PCB 200 to transmit an optical signal into the PCB 200. As stated above, the optical beam path of the PCB 200 may include an optical waveguide 210, a reflector 220, and a drum lens 230. Of course, a groove H₁ may be formed instead of the drum lens 230, if required.

After forming the optical beam path in the PCB 200, the memory package 100 may be combined with the PCB 200 using the solder balls 310 and a refractive index matching unit 320. The refractive index matching unit 320 may be formed between the optical beam path of the support substrate 120 and the optical beam path of the PCB 200, for example, between the drum lens 125 of the support substrate 120 and the drum lens 230 of the PCB 200 to match refractive indices of the two optical beam paths with each other. Meanwhile, the solder balls 310 may function to stably combine the memory package 100 with the PCB 200 and also electrically connect the interconnection of the support substrate 120 with the interconnection of the PCB 200.

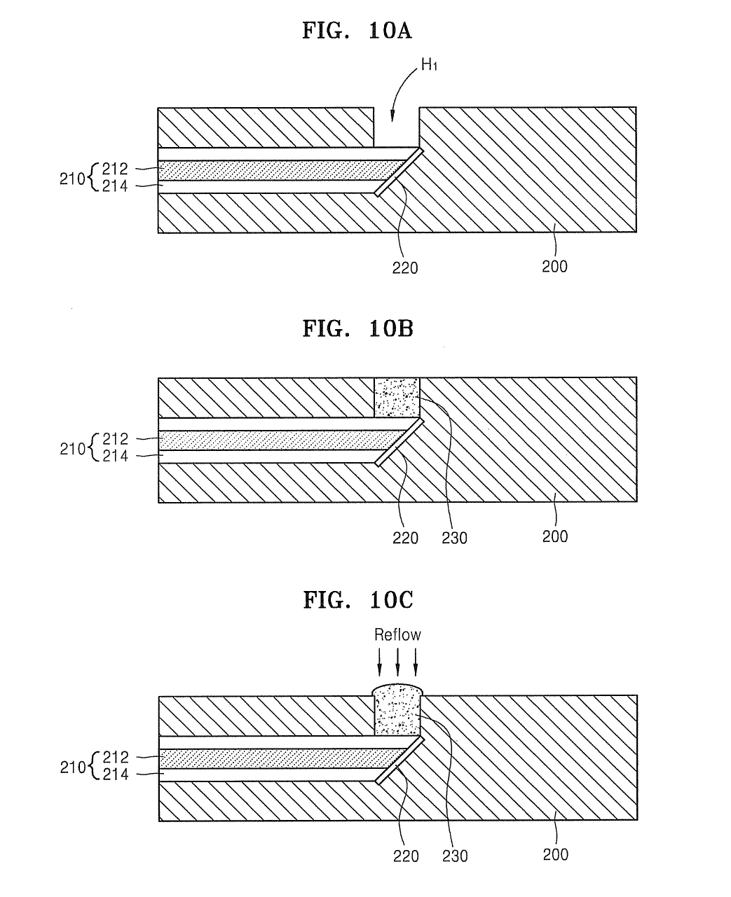

FIGS. 10A through 10C are cross-sectional views illustrating a process of forming a drum lens on a PCB in a method of manufacturing a memory module according to an example embodiment.

Referring to FIG. 10A, to begin with, a predetermined groove H₁ may be formed over a portion of an optical waveguide 210 where a reflector 220 is formed. The groove H₁ may be formed in such a position as to allow light reflected by the reflector 220 to be accurately incident to an optical I/O unit. The groove H₁ may be formed to a predetermined width using photolithography and etching processes.

Referring to FIG. 10B, silicon oxide 230a may be filled in the groove H₁. Meanwhile, a chemical mechanical polishing (CMP) process may be performed to planarize a top surface of the silicon oxide, if required.

Referring to FIG. 10C, the PCB 200 may be heated to a predetermined temperature so that the silicon oxide may be reflowed. Thus, the silicon oxide may be swelled during the reflow process, thereby forming a convex lens having a predetermined radius of curvature. The silicon oxide filling the groove H₁ and the convex lens formed on the silicon oxide may form the drum lens 230.

Although only a process of forming the drum lens 230 on the PCB 200 is described above, a drum lens 125 may be formed in the support substrate 120 using the same process.

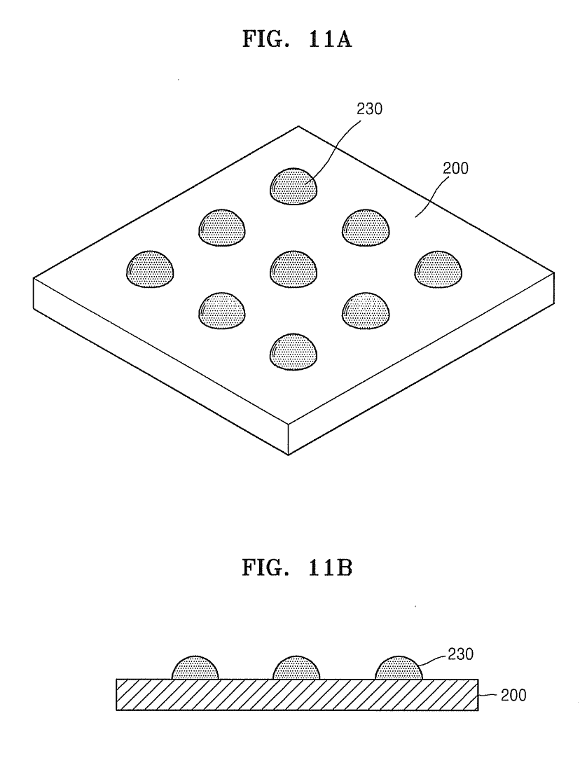

FIGS. 11A and 11B are respectively a plan view and side view of a PCB on which a drum lens is formed.

Referring to FIG. 11A, typically, a plurality of memory packages 100 may be mounted on a PCB 200. Thus, a plurality of drum lenses 230 may be formed on the PCB 200 in positions corresponding to optical I/O units formed in the respective memory packages 100.

FIG. 11B is a side view of the PCB 200 of FIG. 11A.

Referring to FIG. 11B, it can be confirmed that an upper portion of the drum lens 230 has the same structure as a convex lens. Although it is illustrated that the drum lens 230 has a very small radius of curvature to exaggerate the formation of the convex lens, the convex lens fowled in the upper portion of the drum lens 230 may actually have a very large radius of curvature to generate collimated or slightly focused light.

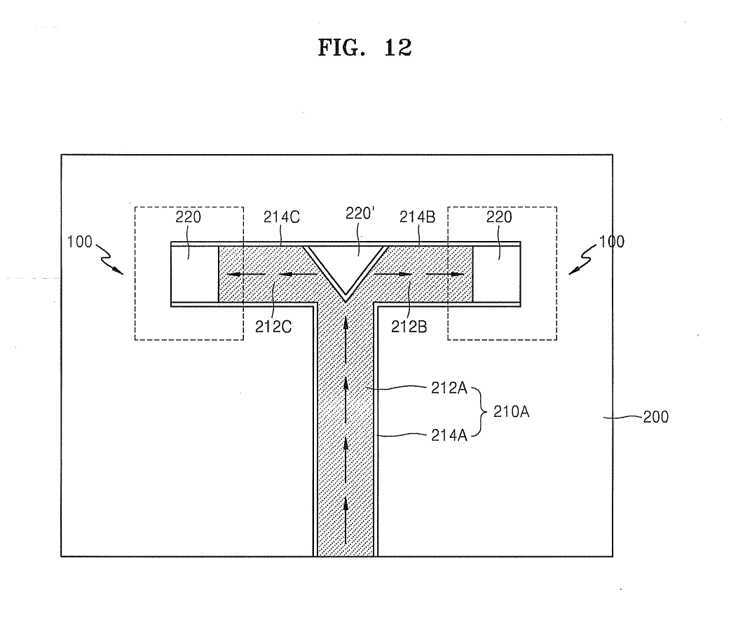

FIG. 12 is another example embodiment of the invention. In this example, an optical wave guide 210A is arranged in a “T” shape to provide light to two different memory packages 100. The “T” shaped wave guide 210 may include a first core 212A which branches into second and third cores 212B and 212C which may form right angles with the first core 212A. The second and third cores 212B and 212C may form the horizontal portion of the “T” shaped configuration with the first core 212A forming the vertical portion. The “T” shaped wave guide 210 may also include a first clad 214A which branches into a second and third clad 214B and 214C. Provided at the intersection of the first, second, and third cores 212A, 212 B, and 212C is a triangular shaped mirror 220′ having an apex directed towards a centerline of the first core 212A. Mirror 220′ directs light to two mirrors 220 which in turn directs the light to memory packages 100 (shown in dashed lines). In this example embodiment, the length of the second and third cores may be the same, however, this example embodiment is not limited thereto in that a length of the second core may be longer than a length of the third core. In addition, the structure of the instant example embodiment need not be T-shaped. For example, the structure could be “Y” shaped or “arrow” shaped.

While the inventive concept has been particularly shown and described with reference to example embodiments thereof, it will be understood that various changes in form and details may be made therein without departing from the spirit and scope of the following claims.

What is claimed is:

1. A memory module comprising:
at least one memory package including an optical signal input/output (I/O) unit and a first optical beam path;
a printed circuit board (PCB) on which the memory package is mounted, the PCB having a second optical beam path configured to transmit an optical signal to the optical signal I/O unit; and
a connecting body configured to mount the memory package on the PCB and match a refractive index of the first optical beam path with a refractive index of the second optical beam path.

2. The module of claim 1, wherein the second optical beam path comprises:
an optical waveguide extending in a horizontal direction of the PCB and having a core and a clad;
a reflector at an end portion of the optical waveguide and configured to reflect light towards the optical signal I/O unit; and
a drum lens extending in a vertical direction of the PCB, the drum lens being configured to one of collimate and focus the light reflected by the reflector in a direction toward the optical signal I/O unit.

3. The module of claim 2, wherein
the core of the optical waveguide includes silicon, and the clad of the optical waveguide includes silicon oxide (SiO₂); and
the drum lens includes silicon oxide, and the drum lens includes a convex lens in a top end of the drum lens facing the optical signal I/O unit.

4. The module of claim 1, wherein the second optical beam path comprises:
an optical waveguide extending in a horizontal direction of the PCB and having a core and a clad; and
a reflector at an end portion of the optical waveguide and configured to reflect light towards the optical signal I/O unit, wherein the PCB includes a groove above the reflector to allow light reflected by the reflector to enter the first optical beam path.

5. The module of claim 1, wherein the optical signal I/O unit includes one of a grating coupler and a Gaussian grating coupler configured to one of selectively input and output the optical signal according to a wavelength thereof.

6. The module of claim 1, wherein the memory package further includes
a memory chip;
a support substrate attached to the memory chip and having an electrical interconnection connected to the memory chip, the first optical beam path being formed in the support substrate to correspond to the second optical beam path in the PCB to enable transmission of the optical signal; and
an encapsulant configured to encapsulate the memory chip.

7. The module of claim 6, wherein the first optical beam path includes a transparent material below the optical signal I/O unit, the transparent material being configured to allow transmission of light.

8. The module of claim 7, wherein the transparent material forms a drum lens that includes a convex lens at a bottom end of the support substrate that faces the PCB.

9. The module of claim 6, wherein the support substrate includes a groove forming the first optical beam path, the groove being configured to allow transmission of light to and from the optical signal I/O unit.

10. The module of claim 1, wherein the connecting body comprises:
solder balls configured to mount the memory package on the PCB; and
a refractive index matching body comprised of a transparent material which allows transmission of the optical signal, the refractive index matching body interposed between the first optical beam path and the second optical beam path and configured to match the refractive index of the first optical beam path with the refractive index of the second optical beam path.

11. An electrical and electronic apparatus comprising:
the memory module of claim 1;
a light source configured to generate a first optical signal to be transmitted to the memory module;
a processor including an operator and controller configured to process and control data;
an optic/electric converter configured to convert a second optical signal transmitted from the memory module into a first electric signal, transmit the first electric signal to the processor, convert a second electric signal transmitted from the processor into a third optical signal, and transmit the third optical signal to the memory module; and
a system board on which the memory module, the light source, the processor, and the optic/electric converter are mounted.

12. The apparatus of claim 11, wherein the second optical beam path comprises:
an optical waveguide extending in a horizontal direction of the PCB and having a core and a clad;
a reflector at an end portion of the optical waveguide and configured to reflect light towards the optical signal I/O unit; and
a drum lens extending in a vertical direction of the PCB, the drum lens being configured to one of collimate and focus the light reflected by the reflector in a direction toward the optical signal I/O unit.

13. The apparatus of claim 11, wherein the optical signal I/O unit includes one of a grating coupler and a Gaussian grating coupler.

14. The apparatus of claim 11, wherein an optical waveguide configured to transmit one of the second and third optical signals is on the system board between the memory module and the optic/electric converter.

15. A method of manufacturing a memory module, comprising:
manufacturing a memory package including an optical signal I/O unit;
forming an optical beam path in a PCB to enable transmission of an optical signal to the optical signal I/O unit; and
mounting the memory package on the PCB using a medium material.

16. The method of claim 15, wherein forming the optical beam path in the PCB comprises:
forming an optical waveguide in the PCB, the optical wave guide including a core and a clad extending in a horizontal direction of the PCB;
forming a reflector at an end of the optical waveguide, the reflector being configured to reflect light towards the optical signal I/O unit;
forming a drum lens in the PCB above the reflector, the drum lens extending in a vertical direction of the PCB, the drum lens being formed to one of collimate and focus the light reflected by the reflector toward the optical signal I/O unit.

17. The method of claim 16, wherein forming the drum lens comprises:
forming a groove in the PCB above the reflector, the groove extending from a surface of the PCB to the optical waveguide;
filling the groove with silicon oxide by deposition; and
convexly forming a top surface of the silicon oxide using one of an annealing and reflow process.

18. The method of claim 15, wherein forming the optical beam path in the PCB comprises:
forming an optical waveguide in the PCB, the optical wave guide including a core and a clad extending in a horizontal direction of the PCB;
forming a reflector at an end of the optical waveguide, the reflector being configured to reflect light towards the optical signal I/O unit;
forming a groove in the PCB above the reflector, the groove extending in a vertical direction of the PCB, the groove being formed to allow the light reflected by the reflector to pass to the optical signal I/O unit.

19. The method of claim 15, wherein one of a grating coupler and a Gaussian grating coupler configured to one of selectively input and output the optical signal according to a wavelength thereof is formed in the optical I/O unit.

20. The method of claim 15, wherein manufacturing the memory package comprises:
forming the optical signal I/O unit in the memory chip;
forming an optical beam path in a support substrate;
attaching the memory chip to the support substrate so that the optical signal I/O unit is aligned with the optical beam path in the support substrate; and
encapsulating the memory chip using an encapsulant.

21. The method of claim 20, wherein forming the optical beam path on the support substrate comprises:
forming a groove in a portion of the support substrate corresponding to the optical signal I/O;
filling the groove with silicon oxide by deposition; and
convexly forming a bottom surface of the silicon oxide using one of an annealing process and a reflow process.

22. The method of claim 20, wherein forming the optical beam path on the support substrate comprises:
forming a groove in a portion of the support substrate corresponding to the optical signal I/O, the groove being configured to pass light to the optical signal I/O.

23. The method of claim 15, wherein
the medium material includes solder balls and a refractive index matching body, and
mounting the memory package on the PCB using the medium material includes
interposing the refractive index matching body between an optical beam path of the memory package and the optical beam path of the PCB to match a refractive index of the optical beam path of the memory package with a refractive index of the optical beam path of the PCB; and
attaching the solder balls to the PCB.
